(19) United States
(12) Patent Application Publication
(10) Pub. No.: US 2026/0164829 A1
(43) Pub. Date: Jun. 11, 2026

(54) IMAGE SENSOR AND IMAGE SENSOR MANUFACTURING METHOD

(71) Applicants: DB HiTek Co., Ltd., Bucheon-si (KR); GPixel Microelectronics Inc., Changchun (CN)

(72) Inventors: Man Lyun HA, Mungyeong-si (KR); Assaf Lahav, Hangzhou City (CN)

(21) Appl. No.: 19/053,989

(22) Filed: Feb. 14, 2025

(30) Foreign Application Priority Data
Dec. 11, 2024 (KR) 10-2024-0183284

(51) Int. Cl. H10F 39/00; H10F 39/18

(52) U.S. Cl. CPC H10F 39/807; H10F 39/014; H10F 39/189; H10F 39/811

(57) ABSTRACT

Proposed are an image sensor and an image sensor manufacturing method, the image sensor being configured such that a plug structure is formed between a floating diode and a metal contact that is electrically connected to the floating diode so that possible damage to a side of a semiconductor layer where the floating diode is formed is prevented.

### CROSS REFERENCE TO RELATED APPLICATION

The present application claims priority to Korean Patent Application No. 10-2024-0183284, filed Dec. 11, 2024, the entire contents of which are incorporated here for all purposes by this reference.

### BACKGROUND

### Technical Field

The present disclosure relates to an image sensor and an image sensor manufacturing method, the image sensor being configured such that a plug structure is formed between a floating diode and a metal contact that is electrically connected to the floating diode so that possible damage to a side of a semiconductor layer where the floating diode is formed is prevented.

### Description of the Related Art

An image sensor is a component of an imaging device generating an image in a cell phone camera or the like. According to a manufacturing process and an application method, the image sensor may be classified into a Charge Coupled Device (CCD) image sensor and a Complementary Metal Oxide Semiconductor (CMOS) image sensor. The CMOS image sensor is widely used as a general semiconductor chip manufacturing process due to a high degree of integration, economic feasibility, and ease of connection with surrounding chips.

FIG. 1 is a cross-sectional view illustrating a conventional image sensor of the present disclosure. Hereinafter, a structure of the conventional image sensor 9 and problems thereof will be described in detail with reference to FIG. 1.

Referring to FIG. 1, a conventional image sensor 9 may include a photo diode 920 provided within a semiconductor layer 910 and a floating diode 930 provided at a side spaced apart from the photo diode 920. In addition, an insulation film layer 940 is formed on the semiconductor layer 910, and a metal contact 950 may be formed in a shape that penetrates the insulation film layer 940. For example, such a metal contact 950 may be formed of tungsten (W), the metal contact 950 may extend in a vertical direction within the insulation film layer 940 and a bottom surface of the metal contact 950 may be connected to the floating diode 930, and an upper surface of the metal contact 950 may be connected to a metal wiring (not illustrated).

As described above, when a reactive ion etching process performed for forming the metal contact 950 in contact with the floating diode 930 is performed, damage may occur to a side semiconductor layer 910 where the floating diode 930 is formed. In addition, when a gap-filling process of a metal layer is performed within the insulation film layer 940 so as to form the metal contact 950, there is also a possibility that the metal layer may penetrate and contaminate the floating diode 930. In the situation described above, dark current in a pixel region may occur, and this may be a factor that reduces the reliability of an element.

In order to solve the above problems, the inventor of the present disclosure will present a new image sensor and a manufacturing method thereof, and the detailed description will be described later.

### DOCUMENT OF RELATED ART

(Patent Document 1) U.S. Pat. No. 9,054,106 B2 “SEMICONDUCTOR STRUCTURE AND METHOD FOR MANUFACTURING THE SAME”

### SUMMARY

Accordingly, the present disclosure has been made keeping in mind the above problems occurring in the related art.

An objective of the present disclosure is to provide an image sensor and an image sensor manufacturing method, the image sensor being configured such that a plug structure is formed between a floating diode and a metal contact that is electrically connected to the floating diode so that possible damage to a side of a semiconductor layer where the floating diode is formed is prevented.

In addition, another objective of the present disclosure is to provide an image sensor and an image sensor manufacturing method, the image sensor being configured such that a plug structure is formed on a floating diode, thereby preventing the floating diode from being contaminated by a metal material when a metal contact is formed.

In addition, still another objective of the present disclosure is to provide an image sensor and an image sensor manufacturing method, the image sensor being configured such that a pinning layer is formed on a surface side of a floating diode, thereby suppressing a leakage current from a surface of a semiconductor layer within a pixel region.

In addition, yet another objective of the present disclosure is to provide an image sensor and an image sensor manufacturing method, the image sensor being configured such that a pinning layer is formed only on a portion of a surface region of a floating diode, thereby ensuring that the floating diode is in contact with a plug structure.

In addition, yet another objective of the present disclosure is to provide an image sensor and an image sensor manufacturing method, the image sensor being configured such that a plug structure is directly connected to a drive gate by a polysilicon film, thereby increasing the process convenience.

In addition, yet another objective of the present disclosure is to provide an image sensor and an image sensor manufacturing method, the image sensor being configured such that a first insulation film provided on a floating diode is removed by a wet etching process, thereby preventing possible damage to a side of a semiconductor layer where the floating diode is formed.

The present disclosure may be implemented by one or more embodiments having some or all of the following configurations, to achieve one or more of the above-described objectives.

According to an aspect of the present disclosure, there is provided an image sensor according to the present disclosure, the image sensor including: a semiconductor layer; a photo diode provided in the semiconductor layer; a floating diode provided in the semiconductor layer; a plug structure provided on the semiconductor layer, the plug structure having a side that is in contact with the floating diode; and a metal contact connected to the plug structure.

According to another aspect of the present disclosure, the image sensor according to the present disclosure may further include a first pinning layer which is provided on a surface side of the photo diode and which is an impurity doped region having a first conductivity type.

According to still another aspect of the present disclosure, the image sensor according to the present disclosure may further include a second pinning layer which is provided on a surface side of the floating diode and which is an impurity doped region having a first conductivity type.

According to yet another aspect of the present disclosure, in the image sensor according to the present disclosure, the second pinning layer may have a width size in a horizontal direction smaller than a width size of the floating diode in the horizontal direction.

According to yet another aspect of the present disclosure, in the image sensor according to the present disclosure, the plug structure may be a polysilicon film.

According to yet another aspect of the present disclosure, in the image sensor according to the present disclosure, the plug structure may be configured such that a bottom surface of the plug structure is connected to the floating diode.

According to yet another aspect of the present disclosure, the image sensor according to the present disclosure may further include a plug insulation film provided between the plug structure and the floating diode, wherein the plug insulation film may be positioned adjacent to one side portion or both side portions on a bottom surface of the plug structure.

According to yet another aspect of the present disclosure, in the image sensor according to the present disclosure, the plug structure may have a stepped part which is provided on the bottom surface of the plug structure and which has a staircase shape.

According to yet another aspect of the present disclosure, the image sensor according to the present disclosure may further include a plug spacer provided on a side wall of the plug structure.

According to yet another aspect of the present disclosure, the image sensor according to the present disclosure may further include a drive gate provided on the semiconductor layer, wherein the drive gate may be physically connected to the plug structure.

According to yet another aspect of the present disclosure, the image sensor according to the present disclosure may further include an element isolation film provided in the semiconductor layer, wherein the drive gate may be connected to the plug structure by a polysilicon film which is in contact with the element isolation film and which extends on the element isolation film.

According to yet another aspect of the present disclosure, there is provided an image sensor according to the present disclosure, the image sensor including: a pixel region that is a region receiving incident light; a logic region provided on a peripheral portion of the pixel region; a semiconductor layer; a photo diode provided in the semiconductor layer within the pixel region; a floating diode provided in the semiconductor layer within the pixel region; a plug structure provided on the semiconductor layer, the plug structure having a side that is in contact with the floating diode; a metal contact connected to the plug structure; and a logic gate including a first gate and a second gate that are provided on the semiconductor layer within the logic region.

According to yet another aspect of the present disclosure, in the image sensor according to the present disclosure, the plug structure may be formed together with the logic gate in the same process.

According to yet another aspect of the present disclosure, the image sensor according to the present disclosure may further include: a drive gate provided on the semiconductor layer; and a polysilicon film provided on the semiconductor layer, the polysilicon film connecting the drive gate and the plug structure to each other from between the drive gate and the plug structure.

According to yet another aspect of the present disclosure, the image sensor according to the present disclosure may further include: a first gate insulation film provided between the first gate and the semiconductor layer; a second gate insulation film provided between the second gate and the semiconductor layer; and a plug insulation film provided between the plug structure and the semiconductor layer, wherein the first gate insulation film may have a vertical thickness larger than a vertical thickness of the second gate insulation film.

According to yet another aspect of the present disclosure, in the image sensor according to the present disclosure, the plug insulation film may have a vertical thickness larger than the vertical thickness of the second gate insulation film.

According to yet another aspect of the present disclosure, in the image sensor according to the present disclosure, at least one side of the floating diode may be surrounded by the photo diode.

According to an aspect of the present disclosure, there is provided an image sensor manufacturing method according to the present disclosure, the image sensor manufacturing method including: forming a first insulation film on a semiconductor layer, the first insulation film having a first thickness; forming a first opening on a floating diode by etching one side of the first insulation film; forming a polysilicon film on the first insulation film so as to fill the first opening; forming a plug structure on a logic gate and the floating diode by etching the polysilicon film, the plug structure having a side in contact with the floating diode; forming an insulation film layer on the semiconductor layer so that the insulation film layer covers the logic gate and the plug structure; and forming a metal contact having a shape that penetrates the insulation film layer so that the metal contact is connected to the plug structure.

According to another aspect of the present disclosure, the image sensor manufacturing method according to the present disclosure may further include: forming a second opening by etching another side of the first insulation film; and forming a second insulation film on the semiconductor layer that is opened by the second opening, the second insulation film having a second thickness, wherein the first thickness may have a value larger than a value of the second thickness.

According to still another aspect of the present disclosure, the image sensor manufacturing method according to the present disclosure may further include forming a spacer on the logic gate and a side wall of the plug structure.

According to the above configurations, the present disclosure has the following effects.

In the present disclosure, since the plug structure is formed between the floating diode and the metal contact that is electrically connected to the floating diode, there is an effect that possible damage to the side of the semiconductor layer where the floating diode is formed is prevented.

In addition, in the present disclosure, since the plug structure is formed on the floating diode, there is an effect that the floating diode is prevented from being contaminated by the metal material when the metal contact is formed.

In addition, in the present disclosure, since the pinning layer is formed on the surface side of the floating diode, there is an effect that a leakage current from the surface of the semiconductor layer within the pixel region is suppressed.

In addition, in the present disclosure, since the pinning layer is formed only on the portion of the surface region of the floating diode, there is an effect of ensuring that the floating diode is in contact with the plug structure.

In addition, in the present disclosure, since the plug structure is directly connected to the drive gate by the polysilicon film, there is an effect that the process convenience is increased.

In addition, in the present disclosure, since the first insulation film provided on the floating diode is removed by the wet etching process, possible damage to the side of the semiconductor layer where the floating diode is formed is prevented.

Meanwhile, though not explicitly mentioned, effects described in the present specification and tentative effects, expected from the technical features of the present specification will be treated as described in the present specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional image sensor;

FIG. 2 is a plan view illustrating an image sensor according to an embodiment of the present disclosure;

FIG. 3 is a plan view illustrating the image sensor according to a first embodiment of the present disclosure;

FIG. 4 is a cross-sectional view illustrating the image sensor according to FIG. 3 taken along line A-A′ in FIG. 3;

FIG. 5 is a plan view illustrating the image sensor according to a second embodiment of the present disclosure;

FIG. 6 is a cross-sectional view illustrating the image sensor according to FIG. 5 taken along line B-B′ in FIG. 5;

FIG. 7 is a cross-sectional view illustrating the image sensor according to FIG. 5 taken along line C-C′ in FIG. 5;

FIG. 8 is a plan view illustrating the image sensor according to a third embodiment of the present disclosure;

FIG. 9 is a cross-sectional view illustrating the image sensor according to FIG. 8 taken along line D-D′ in FIG. 8;

FIG. 10 is a cross-sectional view illustrating the image sensor according to FIG. 8 taken along line E-E′ in FIG. 8; and

FIG. 11 to FIG. 17 are cross-sectional views illustrating an image sensor manufacturing method according to an embodiment of the present disclosure.

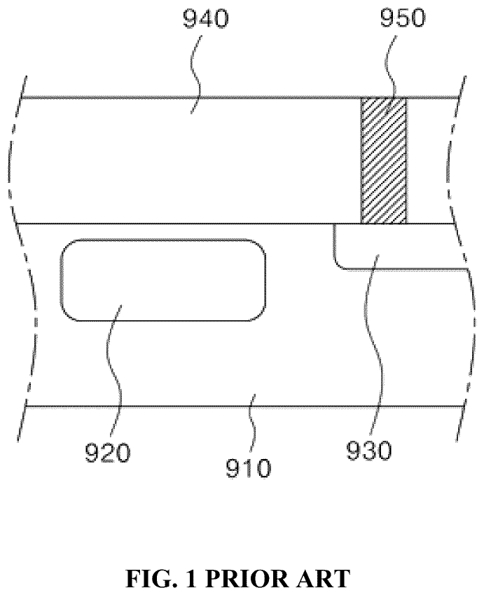

### DETAILED DESCRIPTION

Hereinafter, embodiments of the present disclosure will be described in detail with reference to accompanying drawings. Various changes to the following embodiments are possible and the scope of the present disclosure is not limited to the following embodiments. The patent right of the present disclosure should be defined by the scope and spirit of the present disclosure as disclosed in the accompanying claims. In addition, embodiments of the present disclosure are intended to fully describe the present disclosure to a person having ordinary knowledge in the art to which the present disclosure pertains.

Hereinafter, when it is described that a component (or a layer) is referred to as being on another component (or another layer), it should be understood that the component is directly on the other component, or one or more intervening components (or layers) are also present. In contrast, when it is described that a component is referred to as being directly on to another component, it should be understood that there is (are) no intervening component(s) present. In addition, the terms indicating positions, such as, being located “on”, “upper”, “lower”, “upper side”, “lower side”, “first side”, and “side surface” are intended to mean a relative position of the components.

The terms “first”, “second”, “third”, and so on may be used to describe various items, such as various elements, regions, and/or parts, but the items are not limited by the terms.

In addition, when a specific embodiment may be implemented differently, a specific process order may be performed differently from the described order. For example, two consecutively described processes may be performed substantially at the same time or performed in an order opposite to the described order.

In addition, conductivity types or doped regions of elements may be defined as “p-type” or “n-type” according to main carrier characteristics, but this is only for convenience of description, and the technical idea of the present disclosure is not limited thereto. For example, hereinafter, the “p-type” or “n-type” will be referred to as more general terms a “first conductivity type” or “second conductivity type”. Herein, the first conductivity type may refer to p-type conductivity, and the second conductivity type may refer to n-type conductivity.

In addition, it is to be understood that the terms “heavily” and “lightly” in reference to the doping concentration in an impurity region refer to relative doping concentrations of one impurity region relative to another impurity region.

In addition, it should be noted that an image sensor according to the present disclosure is applicable not only to a frontside illuminated image sensor but also to a backside illuminated image sensor.

Hereinafter, an x-axis direction on the illustrated plan view is set to be a “first direction” and a y-axis direction is set to be a “second direction”.

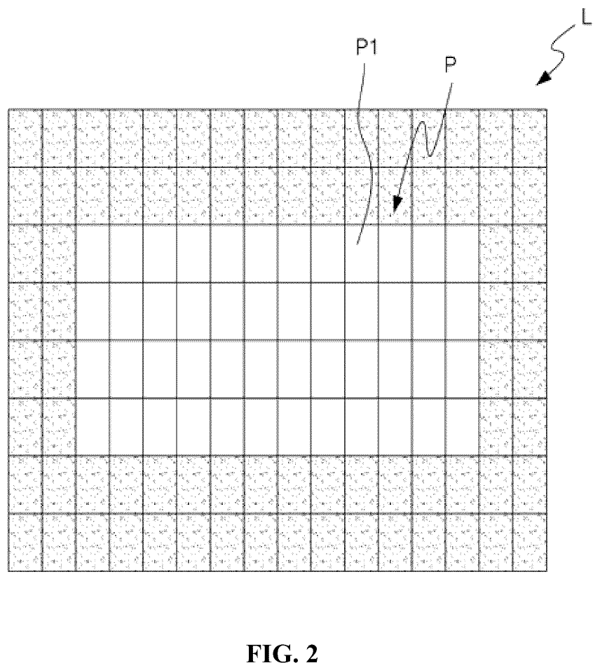

FIG. 2 is a plan view illustrating an image sensor according to an embodiment of the present disclosure.

Referring to FIG. 2, a pixel region P and a logic region L may be formed in an image sensor according to the present disclosure. The pixel region P is a region which absorbs incident light entering from the outside, and the logic region L is a region which forms a peripheral portion of the pixel region P. The pixel region P may include a plurality of unit pixel regions P1. In addition, a pad (not illustrated) configured to be electrically connected to an external terminal may be formed in the logic region L.

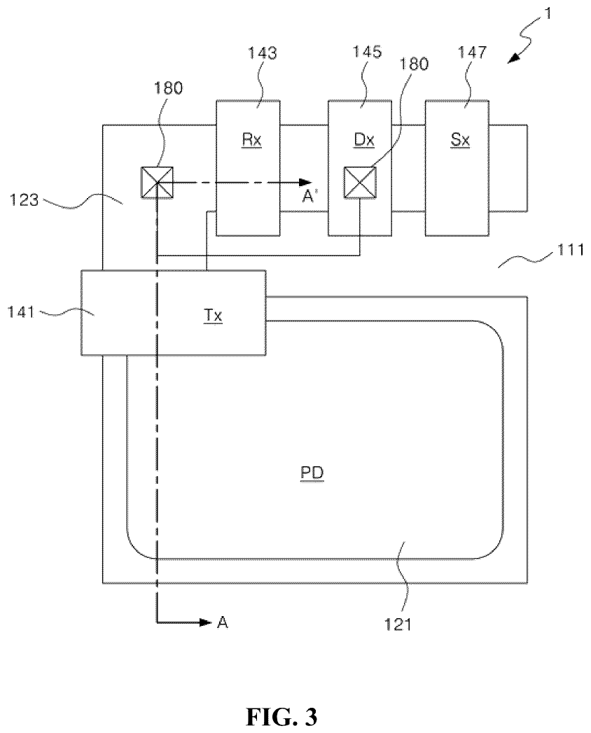

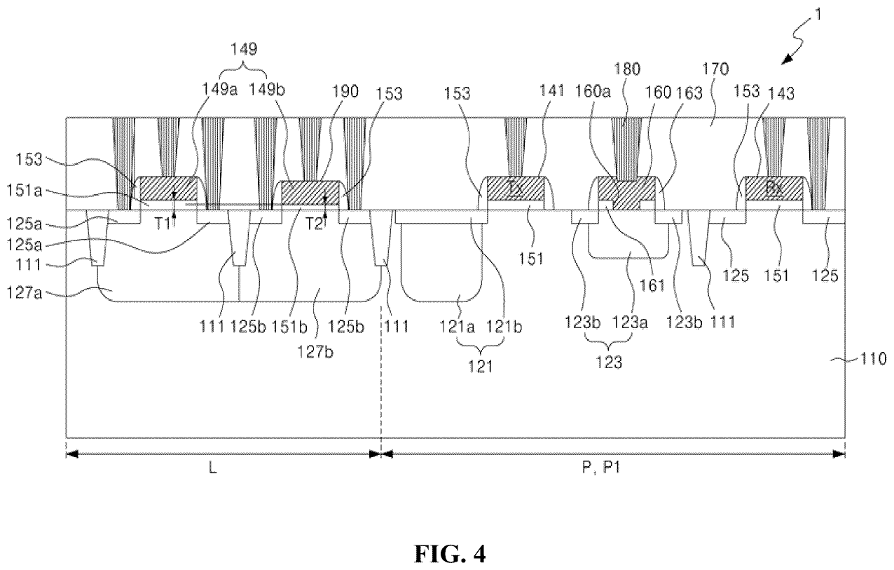

FIG. 3 is a plan view illustrating the image sensor according to a first embodiment of the present disclosure, and FIG. 4 is a cross-sectional view illustrating the image sensor according to FIG. 3 taken along line A-A′ in FIG. 3.

Hereinafter, an image sensor 1 according to the first embodiment of the present disclosure will be described in detail with reference to the accompanying drawings. As an example, the following image sensor may be a CMOS image sensor.

Referring to FIG. 3 and FIG. 4, the present disclosure relates to the image sensor 1. More particularly, the present disclosure relates to the image sensor 1 being configured such that a plug structure is formed between a floating diode and a metal contact that is electrically connected to the floating diode so that possible damage to a side of a semiconductor layer where the floating diode is formed is prevented, thereby blocking an occurrence of dark current in the pixel region P.

To this end, first, the image sensor 1 according to the first embodiment may include a semiconductor layer 110. For example, the semiconductor layer 110 includes an epitaxial layer, and is a configuration commonly formed in the pixel region P and the logic region L. In addition, as an example, the semiconductor layer 110 may be a low-concentration impurity doped region having a first conductivity type. In addition, a plurality of element isolation films 111 formed from a surface of the semiconductor layer 110 to a predetermined depth may be formed by being spaced apart from each other. Such an element isolation film 111 is a configuration that defines an active region, and may be formed by performing a Shallow Trench Isolation (STI) process.

In addition, a photo diode 121 and a floating diode 123 formed by being spaced apart from each other may be formed within the semiconductor layer 110 in the unit pixel region P1. As an example, the photo diode 121 and the floating diode 123 may be formed on a surface side of the semiconductor layer 110. The photo diode 121 is a region in which an electric charge is generated in response to incident light, and the floating diode 123 is a configuration that sequentially reads out the electric charge stored in the photo diode 121 according to a read-out timing. Both the photo diode 121 and the floating diode 123 may be an impurity doped region having a second conductivity type.

It is preferable that the photo diode 121 described above is a pinned photo diode. Such a photo diode 121 may be manufactured by performing an ion implantation process on the semiconductor layer 110 so that a first impurity region 121a having the second conductivity type and a second impurity region 121b having the first conductivity type are formed. At this time, it is preferable that the second impurity region 121b is formed on an upper side of the first impurity region 121a, that the first impurity region 121a is a low-concentration impurity doped region having the second conductivity type, and that the second impurity region 121b is a high-concentration impurity doped region having the first conductivity type compared to the epitaxial layer of the semiconductor layer 110. The first impurity region 121a is a region that functions as a photo diode, and the second impurity region 121b is a region corresponding to a pinning layer.

In addition, it is preferable that the floating diode 123 is also a pinned floating diode. Similar to the photo diode 121, such a floating diode 123 may also include a third impurity region 123a having the second conductivity type and a fourth impurity region 123b having the first conductivity type. At this time, it is preferable that the fourth impurity region 123b is formed on the surface side of the semiconductor layer 110, and that the fourth impurity region 123b is formed only in a portion of the region of the semiconductor layer 110 such that the plug structure 160 and a first side of the floating diode 123 are in contact with each other. For example, it is preferable that the fourth impurity region 123b is not formed on a center side of the floating diode 123 but is formed on a border or an edge side of the floating diode 123. By configuring the fourth impurity region 123b in this manner, leakage current from the surface of the semiconductor layer 110 may be suppressed. The third impurity region 123a is a region that functions as a floating diode, and the fourth impurity region 123b is a region corresponding to a pinning layer. Hereinafter, the pinning layer of the second impurity region 121b of the photo diode 121 will be referred to as a “first pinning layer”, and the pinning layer of the fourth impurity region 123b of the floating diode 123 will be referred to as a “second pinning layer”.

In addition, in the unit pixel region P1 and the logic region L, a plurality of source/drain regions 125 may be spaced apart from each other.

In addition, on the semiconductor layer 110 in the unit pixel region P1, a transmission gate 141, a reset gate 143, a drive gate 145, and a selection gate 147 may be spaced apart from each other.

The source/drain regions 125 described above may be formed within the semiconductor layer 110 with the reset gate 143 provided therebetween. Therefore, a transmission transistor Tx may be formed in the transmission gate 141, a reset transistor Rx may be formed in the reset gate 143, a drive transistor Dx may be formed in the drive gate 145, and a select transistor Sx may be formed in the selection gate 147.

For example, the transmission transistor Tx is a configuration that connects or short-circuits between the photo diode 121 and the floating diode 123, and may be formed between the photo diode 121 and the floating diode 123. In addition, the reset transistor Rx is a configuration formed between the transmission transistor Tx and the drive transistor Dx, and may reset the stored charge of the floating diode 123 by resetting a voltage of the floating diode 123 to a power source voltage.

In addition, the selection transistor Sx is a configuration that amplifies a voltage of the floating diode 123, and the drive transistor Dx is a configuration that selectively outputs the amplified voltage according to a selected signal. As an example, the drive transistor Dx may be formed between the reset transistor Rx and the selection transistor Sx.

In addition, a pair of logic gates 149 may be formed on the semiconductor layer 110 in the logic region L. Hereinafter, the pair of logic gates 149 will be respectively referred to as a “first gate 149a” and a “second gate 149b”. As an example, any one of the first gate 149a and the second gate 149b may be a gate of a PMOS transistor, and the other one of the first gate 149a and the second gate 149b may be a gate of an NMOS transistor. In addition, a high voltage HV may be applied to any one of the first gate 149a and the second gate 149b, and a low voltage LV may be applied to the other one of the first gate 149a and the second gate 149b. Hereinafter, for convenience of description, a gate to which the high voltage HV is applied is referred to as the first gate 149a. The source/drain regions 125 may be formed within the semiconductor layer 110 on both sides of each of the first gate 149a and the second gate 149b.

For example, source/drain regions 125a which are high-concentration impurity doped regions having the first conductivity type may be formed on the both sides of the first gate 149a, and source/drain regions 125b which are high-concentration impurity doped regions having the second conductivity type may be formed on the both sides of the second gate 149b. In addition, within the semiconductor layer 110, a first well region 127a which is the impurity doped region having the second conductivity type may be formed so as to surround the source/drain regions 125a, and a second well region 127b which is the impurity doped region having the first conductivity type may be formed so as to surround the source/drain regions 125b. Hereinafter, the first well region 127a and the second well region 127b are collectively referred to as a well region 127.

Each of the individual gates 141 to 149 described above may include a polysilicon film. In addition, a gate insulation film 151 may be formed between the individual gates 141 to 149 and the semiconductor layer 110. As an example, the gate insulation film 151 may include any one of a silicon oxide film, a high-k dielectric film, and a combination thereof. In addition, the gate insulation film 151 may be formed by an ALD process, a CVP process, a PVD process, or the like. In addition, a first thickness T1 of a first gate insulation film 151a at a lower side of the first gate 149a to which the high voltage HV is applied may have a value larger than a second thickness T2 of a second gate insulation film 151b at a lower side of the second gate 149b to which the low voltage LV is applied (T1>T2). In addition, a gate spacer 153 may be further formed on side walls of each of the individual gates 141 to 149. As an example, such a gate spacer 153 may include an oxide film or a nitride film, but the scope of the present disclosure is not limited thereto.

In addition, the plug structure 160 may be formed on a side of the semiconductor layer 110 where the floating diode 123 is formed. The plug structure 160 is a configuration formed together when the gates 141 to 149 are formed, and may include a polysilicon film as an example. In addition, the gate insulation film 151 may not be formed between the plug structure 160 and the floating diode 123. That is, since the floating diode 123 is required to be electrically connected to the metal contact 180, the gate insulation film 151 may not be formed between the plug structure 160 and the floating diode 123.

Alternatively, a plug insulation film 161 that is the same as the gate insulation film 151 may be formed only in a portion of a region between the plug structure 160 and the floating diode 123. That is, the plug insulation film 161 is formed at a lower side of the plug structure 160, and is formed only in the portion of the region so that the floating diode 123 and the metal contact 180 that is connected to the floating diode 123 are electrically connected to each other, so that the floating diode 123 has a side in contact with the plug structure 160.

Therefore, at least a first side of a bottom surface of the plug structure 160 may be in contact with an upper surface of the floating diode 123. To this end, the plug insulation film 161 may be formed on one side portion on the bottom surface of the plug structure 160, or may be formed on both side portions on the bottom surface of the plug structure 160 by being spaced apart from each other. When the plug insulation film 161 is formed as described above, a stepped part 160a may be formed on the bottom surface of the plug structure 160. The stepped part 160a is a shape corresponding to the plug insulation film 161 on the bottom surface of the plug structure 160, and is formed in a staircase shape. At this time, the plug insulation film 161 may have a value substantially same as the value of the first thickness T1.

In addition, plug spacers 163 may be further formed on both side walls of the plug structure 160. The plug spacer 163 is a configuration corresponding to the gate spacer 153, and may be formed together with the gate spacer 153 in the same process.

In addition, an insulation film layer 170 may be formed on the semiconductor layer 110 such that the insulation film layer 170 covers the individual gates 141 to 149 and the plug structure 160. For example, the insulation film layer 170 may include an oxide film, a nitride film, or an oxide nitride film, but the scope of the present disclosure is not limited by specific examples.

In addition, the plurality of metal contacts 180 may be formed in a vertical direction by penetrating the insulation film layer 170, and may be electrically connected to each of the source/drain regions 125, the individual gates 141 to 149, and the plug structure 160. In addition, the metal contact 180 that is connected to the drive gate 145 and the metal contact 180 that is connected to the plug structure 160 may be electrically connected to each other by a metal wiring (not illustrated).

At this time, each silicide film 190 may be formed on the source/drain regions 125 to which the metal contacts 180 are connected, and on the individual gates 141 to 149. In order to improve contact resistance and thermal stability of the silicide film 190, such a silicide film 190 may be formed by performing a self-aligned silicide (salicide) process by using a metal film formed of such as cobalt (Co), nickel (Ni), titanium (Ti), and so on. In addition, it is preferable that the silicide film 190 is not formed on the plug structure 160.

According to the first embodiment of the present disclosure, a feature of the present disclosure is that the metal contact 180 is not physically and directly connected to the floating diode 123, but is connected to the plug structure 160. Therefore, when an etching process (for example, a reactive ion etching process) for forming the metal contact 180 is performed, damage to the semiconductor layer 110 on the floating diode 123 may be prevented. In addition, contamination of the floating diode 123 by a metal material for forming the metal contact 180 may also be prevented. Therefore, by the plug structure 160, the occurrence of dark current in the pixel region P may be suppressed. This can provide greater advantages when applied to a global shutter type image sensor in which electrons stay in the floating diode 123 for a relatively longer time compared to that of a rolling shutter type image sensor. However, it should be noted that the image sensor 1 according to the present disclosure is not limited to the global shutter type image sensor.

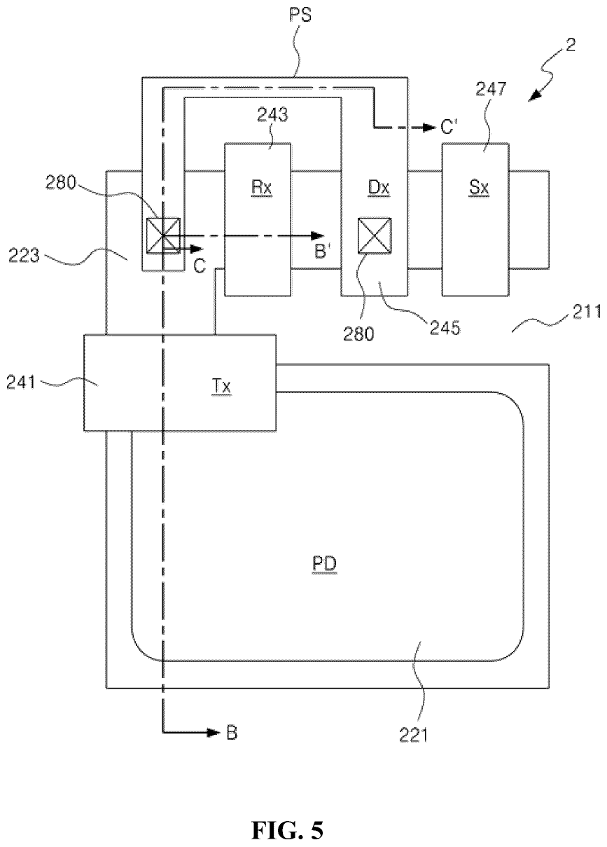

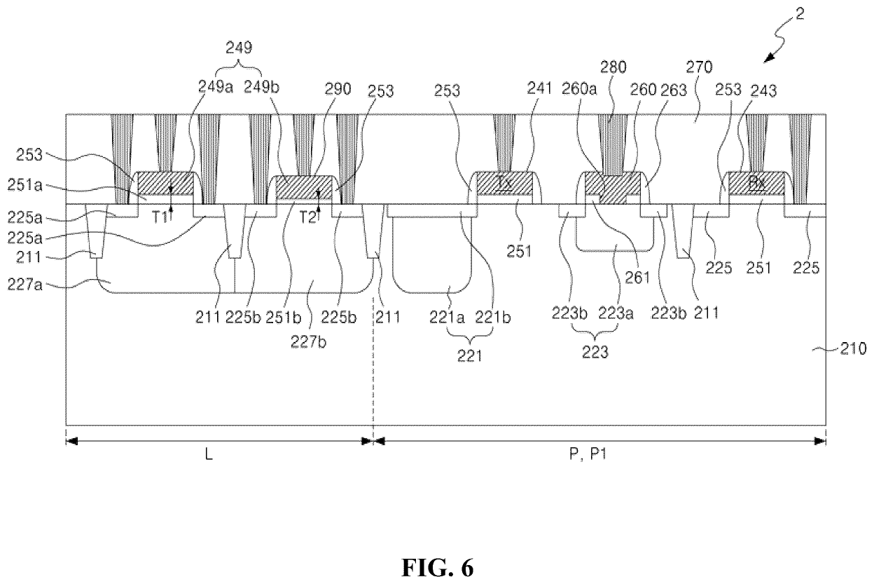

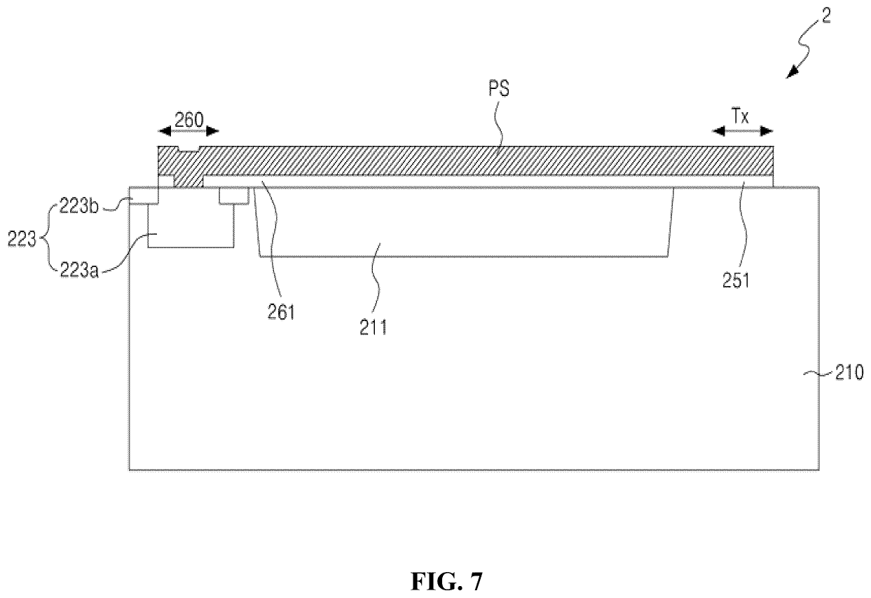

FIG. 5 is a plan view illustrating the image sensor according to a second embodiment of the present disclosure, FIG. 6 is a cross-sectional view illustrating the image sensor according to FIG. 5 taken along line B-B′ in FIG. 5, and FIG. 7 is a cross-sectional view illustrating the image sensor according to FIG. 5 taken along line C-C′ in FIG. 5.

Hereinafter, an image sensor 2 according to a second embodiment of the present disclosure will be described in detail with reference to the accompanying drawings. Since the image sensor 2 according to the second embodiment differs from the image sensor 1 according to the first embodiment only in a plug structure 260. Therefore, hereinafter, only the plug structure 260 will be described in detail. In addition, for the configuration corresponding to the image sensor 1 according to the first embodiment, the first digit of the reference numeral has been changed from “1” to “2”.

Referring to FIG. 5 to FIG. 7, the image sensor 2 according to the second embodiment has the plug structure 260. The plug structure 260 may be connected to a drive gate 245. As an example, a single polysilicon film (PS) may extend from a region in which the drive transistor Dx is formed on a semiconductor layer 210 to a region in which the floating diode 223 is formed. At this time, the polysilicon film PS may extend across an element isolation film 211 between the region in which the drive transistor Dx is formed and the region in which the floating diode 223 is formed.

In addition, a gate insulation film 251 and a plug insulation film 261 may be formed between the polysilicon film PS and the semiconductor layer 210. Such a gate insulation film 251 and a plug insulation film 261 may have a side that is physically connected to each other. As an example, the gate insulation film 251 and the plug insulation film 261 may be formed as respective single structures. At this time, it is preferable that the plug insulation film 261 is formed such that the plug insulation film 261 partially covers an upper surface of the floating diode 223. Alternatively, as another example, the plug insulation film 261 that covers at least a portion of the upper surface of the floating diode 223 may not be formed. That is, between the polysilicon film PS and the semiconductor layer 210, the gate insulation film 251 extends across the device separator 211 to a side adjacent to the floating diode 223, and may be formed such that there is no side covering the floating diode 223.

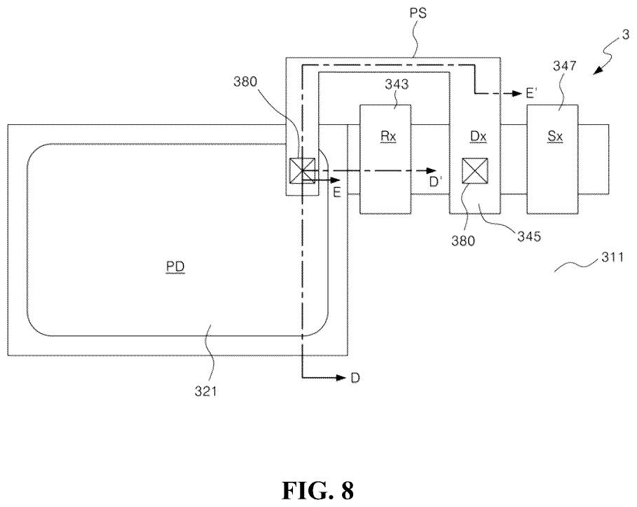

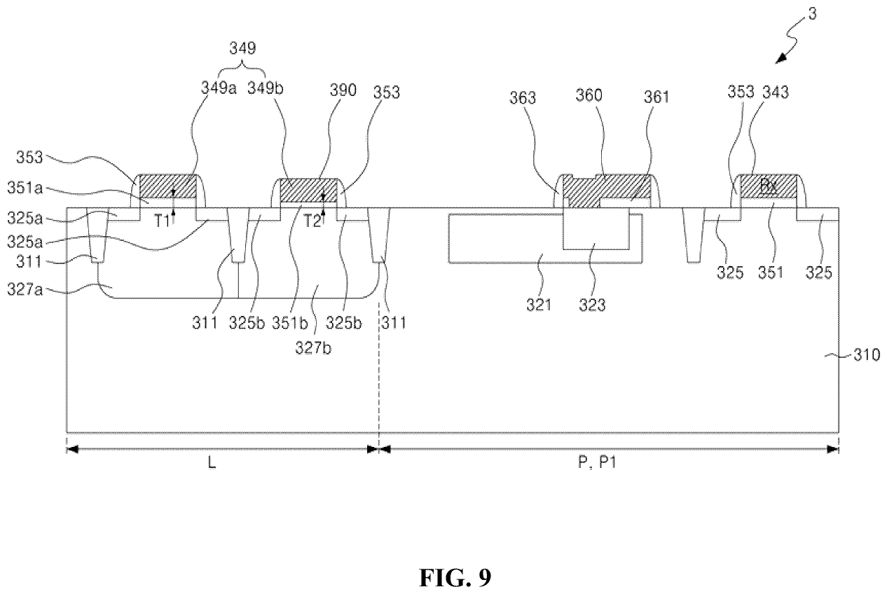

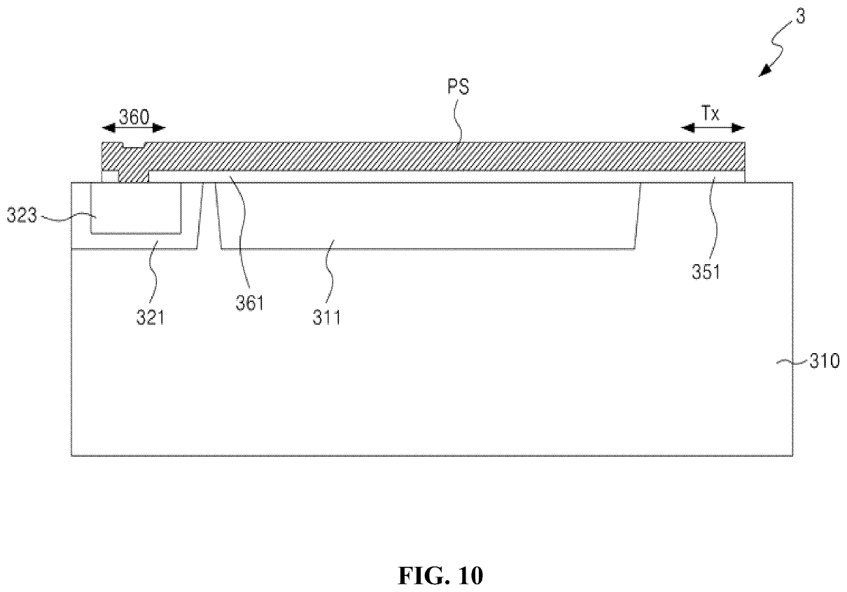

FIG. 8 is a plan view illustrating the image sensor according to a third embodiment of the present disclosure, FIG. 9 is a cross-sectional view illustrating the image sensor according to FIG. 8 taken along line D-D′ in FIG. 8, and FIG. 10 is a cross-sectional view illustrating the image sensor according to FIG. 8 taken along line E-E′ in FIG. 8.

Hereinafter, an image sensor 3 according to a third embodiment of the present disclosure will be described in detail with reference to the accompanying drawings. The image sensor 3 according to the third embodiment may be an X-ray sensor as an example, and the transmission transistor may be not be formed. In addition, for the configuration corresponding to the image sensor 1 according to the first embodiment, the first digit of the reference numeral has been changed from “1” to “3”.

Referring to FIG. 8 to FIG. 10, the image sensor 3 according to the third embodiment may include a floating diode 323 within a photo diode 321 in a semiconductor layer 310. In addition, a plug structure 360 is formed on the photo diode 321, and the plug structure 360 may be substantially the same as the plug structure 160 according to the first embodiment or the plug structure 260 according to the second embodiment.

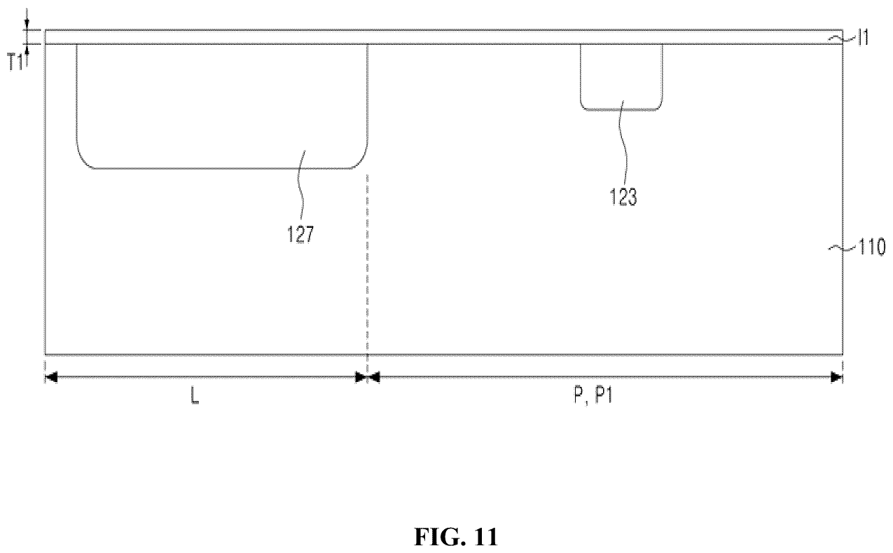

FIG. 11 to FIG. 17 are cross-sectional views illustrating an image sensor manufacturing method according to an embodiment of the present disclosure. In FIG. 11 to FIG. 19, it should be noted that peripheral structures (the transmission transistor, the photo diode, and so on) of the floating diode are omitted.

Hereinafter, an image sensor manufacturing method according to an embodiment of the present disclosure will be described in detail with reference to the accompanying drawings. For convenience of description, hereinafter, only a process of forming the plug structure 160 on the semiconductor layer 110 will be described.

Referring to FIG. 11, first, a first insulation film I1 may be formed on the semiconductor layer 110. The first insulation film I1 may include any one of a silicon oxide film, a high-k dielectric film, and a combination thereof. As an example, the first insulation film I1 may be a silicon oxide film formed by performing a thermal oxidation process. At this time, the first insulation film I1 may have the first thickness T1 along the vertical direction.

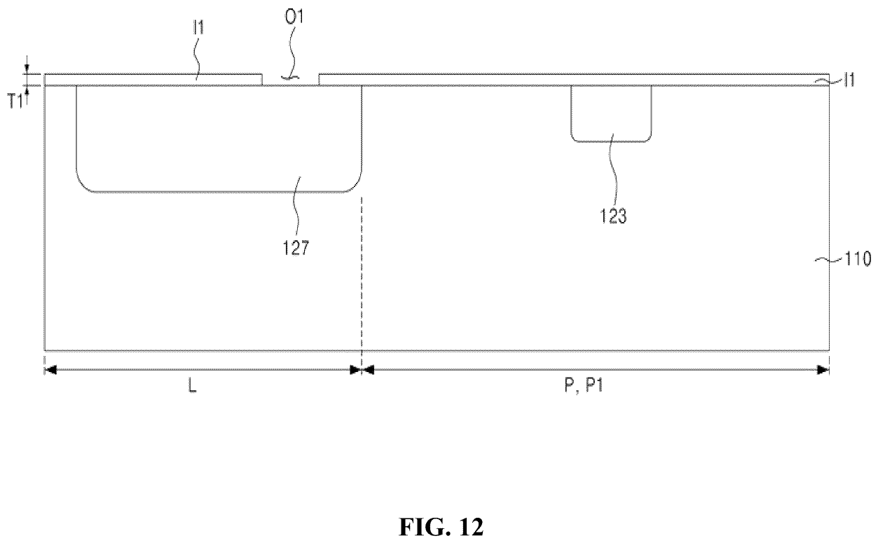

Referring to FIG. 12, after the first insulation film I1 is formed on the semiconductor layer 110, the first insulation film I1 at a side where the second gate 149b is formed may then be removed. For example, the first insulation film I1 at the side where the second gate 149b is formed may be removed by performing an etching process after a mask pattern (not illustrated) is formed on the first insulation film I1. By this process, a first opening O1 is formed on the first insulation film I1 at the side where the second gate 149b is formed, so that an upper surface of the semiconductor layer 110 may be exposed.

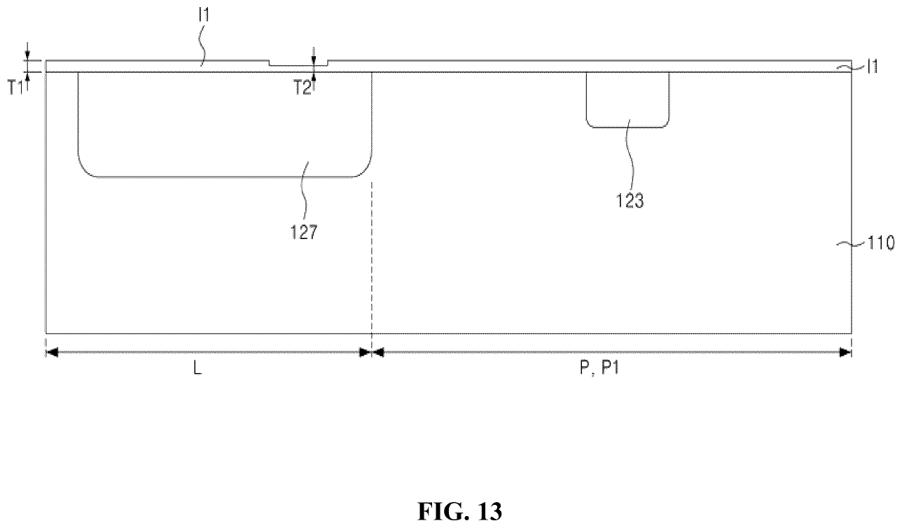

Referring to FIG. 13, as a subsequent process, a second insulation film I2 may be formed on the semiconductor layer 110 at a side of the first opening O1. The second insulation film I2 may include any one of a silicon oxide film, a high-k dielectric film, and a combination thereof. As an example, the second insulation film I2 may be a silicon oxide film formed by performing a thermal oxidation process. In addition, the second insulation film I2 has the second thickness T2 along the vertical direction, and the second thickness T2 may have a value smaller than a value of the first thickness T1 (T2>T1).

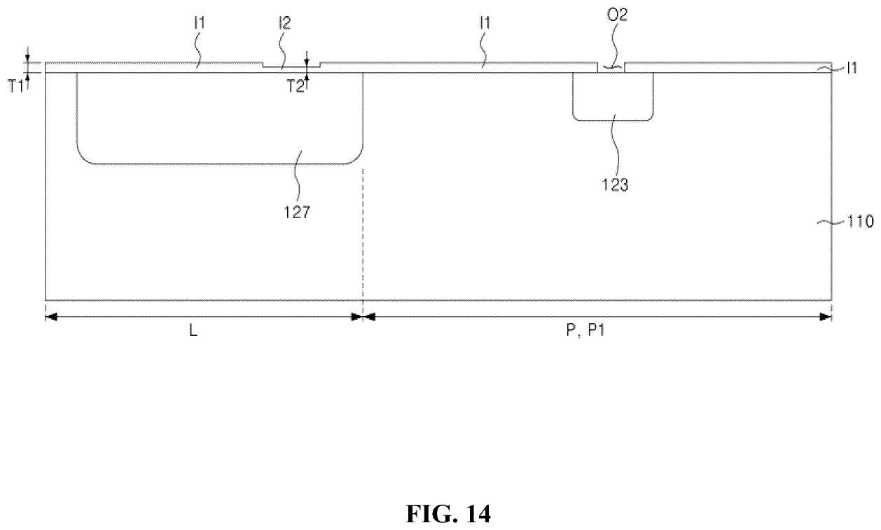

Referring to FIG. 14, after the second insulation film I2 is formed on the semiconductor layer 110, the first insulation film I1 on the upper surface of the semiconductor layer 110 where the floating diode 123 is formed may be removed so that at least one side of the floating diode 123 is opened. This may be realized by performing an etching process, e.g., a wet etching process, by utilizing a mask pattern (not illustrated) on the first insulation film I1. Therefore, a second opening O2 may be formed on an upper side of the floating diode 123. As the wet etching process is performed in this manner, damage to the semiconductor layer 110 may be prevented. In the example described above, it is described that the second opening O2 is formed after the first opening O1 is formed. However, in some situations, the second opening O2 may be formed first or the pair of openings O1 and O2 may be formed together in the same process, and there is no specific limitation.

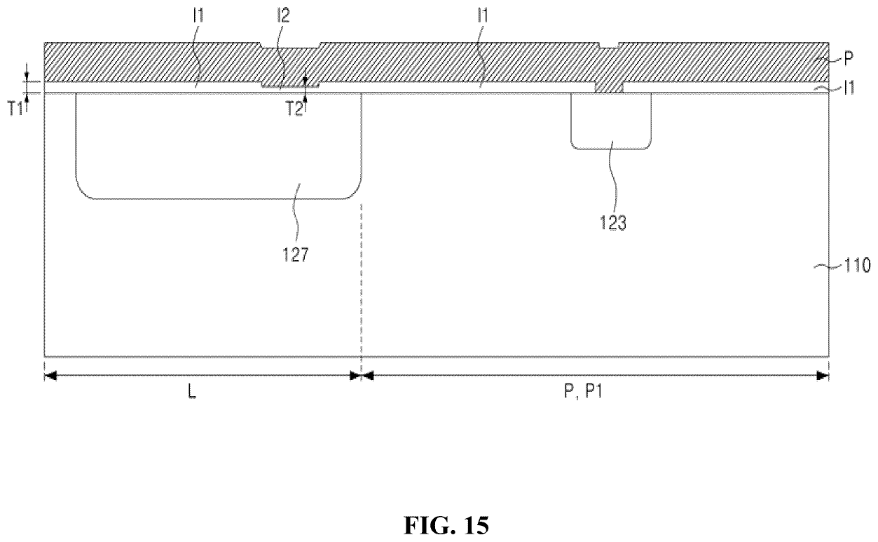

Referring to FIG. 15, the polysilicon film PS may then be deposited on the first insulation film I1 and on the second insulation film I2 so that the openings O1 and O2 are filled.

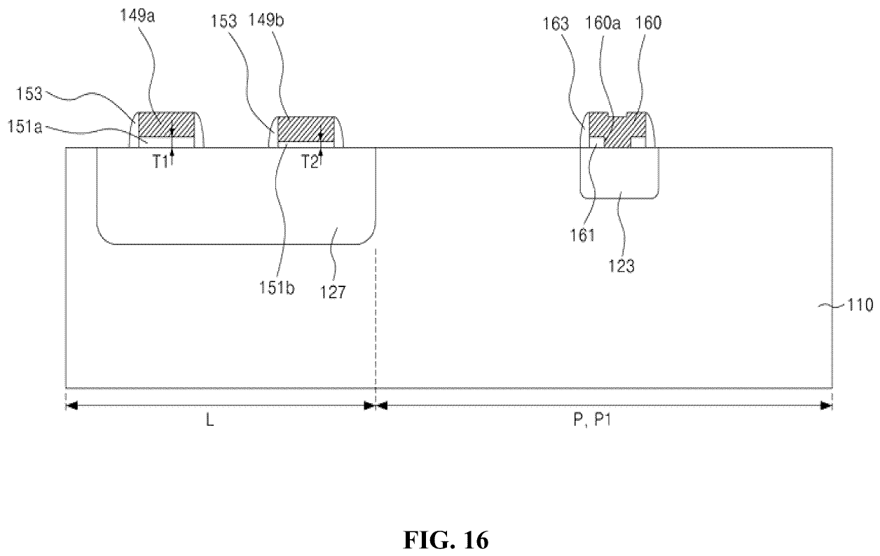

Referring to FIG. 16, after the polysilicon film PS is deposited, the polysilicon film PS is etched and the first insulation film I1 at a lower side of the polysilicon film PS is etched according to a situation, so that the individual gates 141 to 149 and the plug structure 160 may be formed. In addition, the gate insulation film 151 is formed on each lower side of the individual gates 141 to 149, and the plug insulation film 161 may be formed or may not be formed on the lower side of the plug structure 160. In addition, the first gate insulation film 151a at the lower side of the first gate 149a may have the first thickness T1, and the second gate insulation film 151b at the lower side of the second gate 149b may have the second thickness T2.

Subsequently, the gate spacers 153 may be formed on the side walls of each of the individual gates 141 to 149, and the plug spacers 163 may be formed on the side walls of the plug structure 160. This process may be realized by performing an etching process after a third insulation film (not illustrated) is deposited so that the third insulation film covers the individual gates 141 to 149 and the plug structure 160. Then, by performing an ion implantation process in the semiconductor layer 110, the source/drain regions 125 may be formed.

Then, a self-aligned silicide (salicide) process forming the silicide film 190 on the source/drain regions 124 and the upper side of each of the individual gates 141 to 149 may be performed.

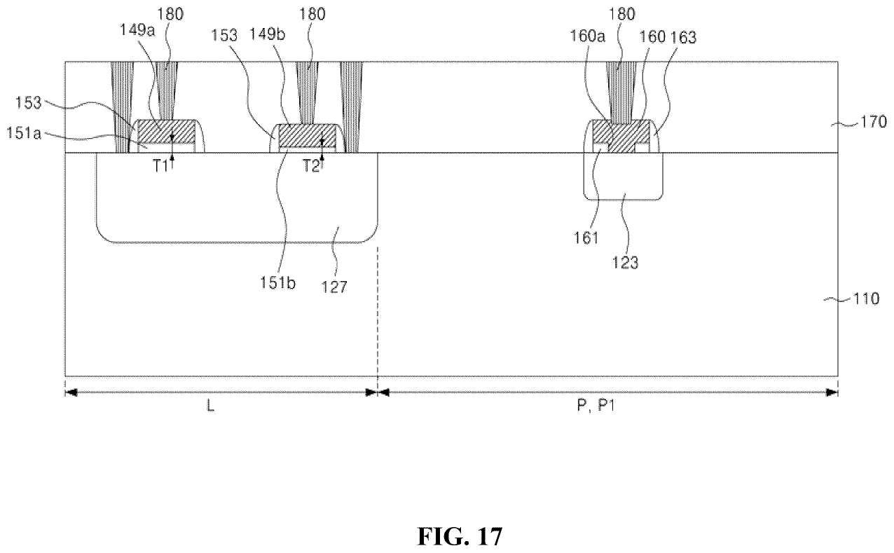

Referring to FIG. 17, the insulation film layer 170 may be formed on the semiconductor layer 110 so that the insulation film layer 170 covers the individual gates 141 to 149 and the plug structure 160. Then, the insulation film layer 170 may be etched by utilizing a mask pattern (not illustrated), and then a gap-filling process of a metal layer may be formed, thereby being capable of forming the metal contact 180.

The foregoing detailed description is for illustrative purposes only. Furthermore, the description provides an embodiment of the present disclosure and the present disclosure may be used in other various combination, changes, and environments. That is, the present disclosure may be changed or modified within the scope of the present disclosure described herein, a range equivalent to the description, and/or within the knowledge or technology in the related art. The embodiments show an optimum state for achieving the spirit of the present disclosure, and various modification required for specific applications and uses of the present disclosure are also possible. Therefore, the detailed description of the present disclosure is not intended to limit the present disclosure in the embodiment.

What is claimed is:

1. An image sensor comprising:
a semiconductor layer;
a photo diode positioned in the semiconductor layer;
a floating diode positioned in the semiconductor layer;
a plug structure positioned on the semiconductor layer, the plug structure having a side in contact with the floating diode; and
a metal contact connected to the plug structure.

2. The image sensor of claim 1, further comprising:
a first pinning layer positioned on a surface side of the photo diode, the first pinning layer being an impurity doped region having a first conductivity type.

3. The image sensor of claim 1, further comprising:
a second pinning layer positioned on a surface side of the floating diode, the second pinning layer being an impurity doped region having a first conductivity type.

4. The image sensor of claim 3, wherein the second pinning layer has a width size in a horizontal direction smaller than a width size of the floating diode in the horizontal direction.

5. The image sensor of claim 1, wherein the plug structure comprises a polysilicon film.

6. The image sensor of claim 1, wherein the plug structure has a bottom surface in contact with the floating diode.

7. The image sensor of claim 1, further comprising:
a plug insulation film positioned between the plug structure and the floating diode,
wherein the plug insulation film is positioned adjacent to at least one side of a bottom surface of the plug structure.

8. The image sensor of claim 7, wherein the plug structure has a step-shaped part on the bottom surface of the plug structure.

9. The image sensor of claim 1, further comprising:
a plug spacer positioned on a side wall of the plug structure.

10. The image sensor of claim 1, further comprising:
a drive gate positioned on the semiconductor layer,
wherein the drive gate is physically connected to the plug structure.

11. The image sensor of claim 10, further comprising:
an element isolation film positioned in the semiconductor layer,
wherein the drive gate is connected to the plug structure by a polysilicon film, the polysilicon film being in contact with the element isolation film and extending on the element isolation film.

12. An image sensor comprising:
a pixel region configured to receive incident light;
a logic region positioned on a peripheral portion of the pixel region;
a semiconductor layer;
a photo diode positioned in the semiconductor layer within the pixel region;
a floating diode positioned in the semiconductor layer within the pixel region;
a plug structure positioned on the semiconductor layer, the plug structure having a side in contact with the floating diode;
a metal contact connected to the plug structure; and
a logic gate comprising a first gate and a second gate positioned on the semiconductor layer within the logic region.

13. The image sensor of claim 12, wherein the plug structure is formed together with the logic gate in a same process.

14. The image sensor of claim 12, further comprising:
a drive gate positioned on the semiconductor layer; and
a polysilicon film positioned on the semiconductor layer, the polysilicon film connecting the drive gate and the plug structure to each other.

15. The image sensor of claim 12, further comprising:
a first gate insulation film positioned between the first gate and the semiconductor layer;
a second gate insulation film positioned between the second gate and the semiconductor layer; and
a plug insulation film positioned between the plug structure and the semiconductor layer,
wherein the first gate insulation film has a vertical thickness larger than a vertical thickness of the second gate insulation film.

16. The image sensor of claim 15, wherein the plug insulation film has a vertical thickness larger than the vertical thickness of the second gate insulation film.

17. The image sensor of claim 12, wherein at least one side of the floating diode is surrounded by the photo diode.

18. An image sensor manufacturing method comprising:
forming a first insulation film on a semiconductor layer, the first insulation film having a first thickness;
forming a first opening on a floating diode by etching one side of the first insulation film;
forming a polysilicon film on the first insulation film to fill the first opening;
forming a plug structure on a logic gate and the floating diode by etching the polysilicon film, the plug structure having a side in contact with the floating diode;
forming an insulation film layer on the semiconductor layer to cover the logic gate and the plug structure; and
forming a metal contact having a shape that penetrates the insulation film layer, allowing the metal contact to be connected to the plug structure.

19. The image sensor manufacturing method of claim 18, further comprising:
forming a second opening by etching another side of the first insulation film; and
forming a second insulation film on the semiconductor layer that is opened by the second opening, the second insulation film having a second thickness,
wherein the first thickness has a value larger than a value of the second thickness.

20. The image sensor manufacturing method of claim 18, further comprising:
forming a spacer on the logic gate and a side wall of the plug structure.
